(19) United States
(12) Patent Application Publication
(10) Pub. No.: US 2015/0295546 A1
(43) Pub. Date: Oct. 15, 2015

(54) AMPLIFIER BANDWIDTH EXTENSION

(71) Applicant: FUJITSU LIMITED, Kawasaki-shi (JP)

(72) Inventor: Jian Hong JIANG, Los Altos, CA (US)

(73) Assignee: FUJITSU LIMITED, Kawasaki-shi (JP)

(21) Appl. No.: 14/249,191

(22) Filed: Apr. 9, 2014

(51) Int. Cl. H03F 1/42; H03F 3/45; H03F 1/56

(52) U.S. Cl. CPC H03F 1/42; H03F 1/56; H03F 3/45071; H03F 2200/171

(57) ABSTRACT

According to at least one embodiment described herein an amplifier may include an amplifying circuit having an output. The amplifier may also include a bandwidth extension circuit coupled to the output of the amplifying circuit. The bandwidth extension circuit may include an active device and a resistor. The active device and the resistor may be configured to create an inductance that increases a bandwidth of the amplifier.

### FIELD

The embodiments discussed herein are related to extending a bandwidth of an amplifier.

### BACKGROUND

Many amplifiers, especially differential amplifiers, are used for high-speed applications that operate at high frequencies. Accordingly, increasing the bandwidth of the amplifiers may increase the usability of the amplifiers, especially as frequency requirements for the amplifiers continue to increase.

The subject matter claimed herein is not limited to embodiments that solve any disadvantages or that operate only in environments such as those described above. Rather, this background is only provided to illustrate one example technology area where some embodiments described herein may be practiced.

### SUMMARY

According to at least one embodiment described herein, an amplifier may include an amplifying circuit having an output. The amplifier may also include a bandwidth extension circuit coupled to the output of the amplifying circuit. The bandwidth extension circuit may include an active device and a resistor. The active device and the resistor may be configured to create an inductance that increases a bandwidth of the amplifier.

The object and advantages of the embodiments will be realized and achieved at least by the elements, features, and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

Example embodiments will be described and explained with additional specificity and detail through the use of the accompanying drawings in which:

FIG. 1A illustrates an example amplifier that includes a bandwidth extension circuit configured to increase a bandwidth of the amplifier;

FIG. 1B illustrates the amplifier of FIG. 1A with an example configuration of the bandwidth extension circuit;

FIG. 2A illustrates an example differential amplifier that includes bandwidth extension circuits configured to increase a bandwidth of the differential amplifier;

FIG. 2B illustrates the differential amplifier of FIG. 2A with an example configuration of the bandwidth extension circuits; and

FIG. 3 illustrates a graph that includes example plots that illustrate that a bandwidth extension circuit described herein may increase the bandwidth of an amplifier.

### DESCRIPTION OF EMBODIMENTS

Amplifiers such as differential amplifiers are increasingly used for high-speed applications such that increasing the bandwidth of the amplifiers is often desired. Often the bandwidth of an amplifier may be affected by a loading resistance (Rcl) of the amplifier as well as a capacitance (Cld) at an output node of the amplifier. For example, the amplifier may have a transfer function that represents the frequency response of the amplifier, where a pole of the transfer function—which may affect the upper limit of the bandwidth of the amplifier—may be expressed by Rcl*Cld.

In some embodiments, the bandwidth of the amplifier may be increased by at least partially cancelling out the capacitance Cld, which may at least partially cancel out the pole that may be associated with the capacitance Cld and the resistance Rcl. As detailed below, a bandwidth extension circuit may be configured to generate an inductance at the output node of the amplifier that may at least partially cancel out the capacitance Cld. In particular, the bandwidth extension circuit may generate a zero for the transfer function that is somewhat close to the pole associated with the capacitance Cld and the loading resistance Rcl, (e.g., approximately equal to) such that the zero may at least partially cancel out the pole associated with the capacitance Cld and the resistance Rcl.

To generate the inductance at the output node of the amplifier that increases the bandwidth of the amplifier, the bandwidth extension circuit may include an active device (e.g., a transistor) and a resistor. Using the active device and resistor to generate the inductance may use less space than using a traditional inductor. In some embodiments, using the active device and resistor to generate the inductance may allow for the entire amplifier, including the bandwidth cancellation circuit, to be included on the same integrated chip.

Embodiments of the present disclosure will be explained with reference to the accompanying drawings.

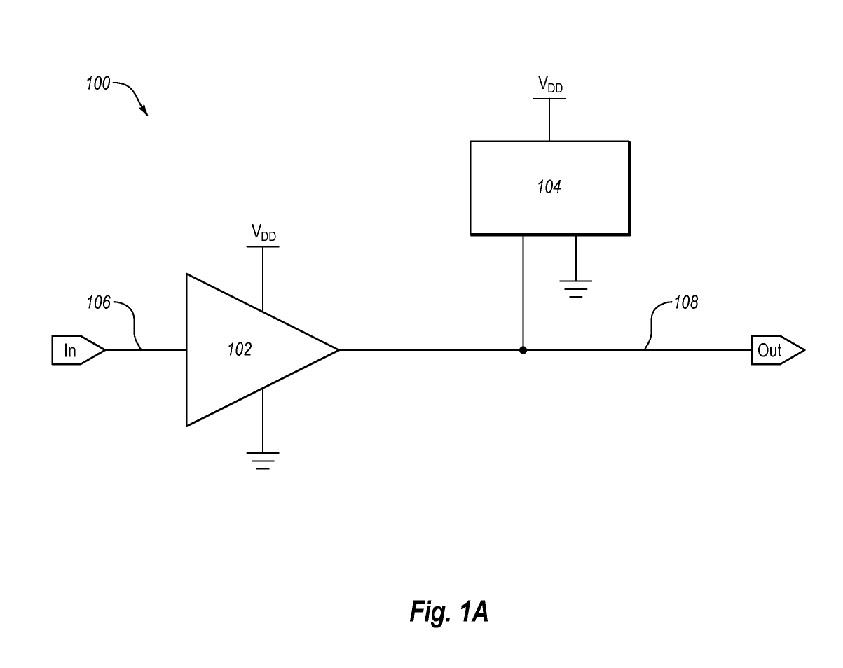

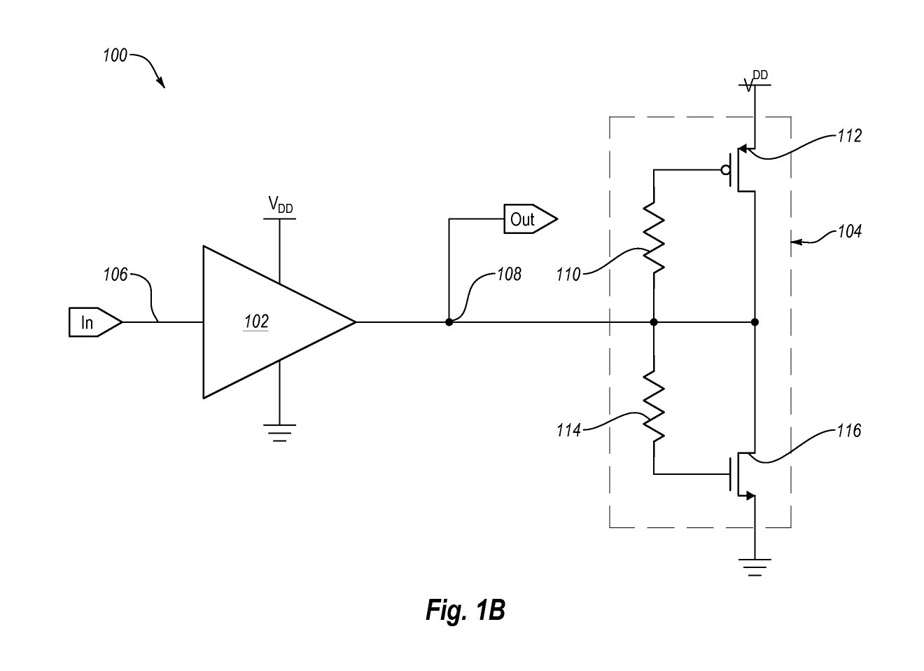

FIG. 1A illustrates an example amplifier 100 that includes a bandwidth extension circuit 104 configured to increase a bandwidth of the amplifier 100, according to at least one embodiment disclosed herein. The amplifier 100 may also include an input node 106, an amplifying circuit 102, and an output node 108. The amplifying circuit 102 may be any suitable circuit configured to receive an input signal at the input node 106, apply a gain to the input signal, and output the input signal with the applied gain as an output signal at the output node 108.

The bandwidth of the amplifier 100 may be affected, and in some instances limited, by an output capacitance (Cₒᵤₜ) at the output node 108 and a loading resistance (R₁) of the amplifying circuit 102. For example, the amplifier 100 may have a transfer function that represents the frequency response of the amplifier 100. The transfer function may have a pole due to R₁ and Cₒᵤₜ that may affect the upper limit of the bandwidth of the amplifier 100. The pole due to R₁ and Cₒᵤₜ may be expressed by R₁*Cₒᵤₜ.

The bandwidth extension circuit 104 may be coupled to the output node 108 and may be configured to generate an inductance that may at least partially cancel out the output capacitance Cₒᵤₜ. As detailed below with respect to FIG. 1B, in some embodiments, the bandwidth extension circuit 104 may include one or more active devices and resistors configured to generate the inductance. In some embodiments, the bandwidth extension circuit 104 may be configured based on the transfer function of the amplifier 100.

For example, as indicated above, the transfer function may have a pole that represents the effect of the output capacitance Cₒᵤₜ and the loading resistance R₁ on the bandwidth of the amplifier 100. The bandwidth extension circuit 104 may produce a zero for the transfer function that may at least partially cancel out the pole and that represents the effect of the bandwidth extension circuit 104 on the bandwidth of the amplifier 100. The closer the zero is placed to the pole, the more the zero cancels out the pole, which may increase the bandwidth of the amplifier 100. Therefore, as detailed further below, in some embodiments, the bandwidth extension circuit 104 may be configured to produce a zero for the transfer function that is close enough to the pole to at least partially cancel out the pole. In some embodiments, the bandwidth extension circuit 104 may be configured to produce a zero for the transfer function that is approximately equal to, or equal to, the pole.

FIG. 1B illustrates the amplifier 100 with an example configuration of the bandwidth extension circuit 104, according to at least one embodiment described herein. The bandwidth extension circuit 104 of FIG. 1B may include resistors 110 and 114 as well as a p-type metal oxide semiconductor (PMOS) transistor 112 (referred to hereinafter as “transistor 112”) and an n-type metal oxide semiconductor (NMOS) transistor 116 (referred to hereinafter as “transistor 116”). The transistor 112 and the transistor 116 may be the active devices of the bandwidth extension circuit 104.

In the illustrated embodiment, the source of the transistor 112 may be coupled to a supply voltage V_{DD} and the source of the transistor 116 may be coupled to ground. Further, the transistor 112 and the transistor 116 may each be coupled to the output node 108 at their respective drains. Further, as illustrated in FIG. 1B, the resistor 110 may be coupled between the output node 108 and the gate of the transistor 112. The resistor 114 may be similarly coupled between the output node 108 and the gate of the transistor 116.

In the illustrated embodiment, the resistor 110 and the transistor 112 configured in the manner illustrated may generate a first inductance that may produce a first zero in the transfer function of the amplifier 100. The first zero may be close to the pole associated with the output capacitance Cₒᵤₜ and the loading resistance R₁. The first zero may be adjusted to be close to the pole by adjusting the resistance of the resistor 110 such that the first zero may at least partially cancel out the pole. In some embodiments, the resistance of the resistor 110 may be selected such that the first zero may be approximately equal to the pole such that the first zero may substantially cancel out the pole.

The resistor 114 and the transistor 116 configured in the manner illustrated may similarly generate a second inductance that may produce a second zero in the transfer function of the amplifier 100. The second zero, like the first zero, may be close to the pole associated with the output capacitance Cₒᵤₜ and the loading resistance R₁ such that the second zero may at least partially cancel out the pole. The second zero may be adjusted to be close to the pole by adjusting the resistance of the resistor 114. In some embodiments, the resistance of the resistor 114 may be selected such that the second zero may be approximately equal to the pole such that the second zero may substantially cancel out the pole.

As illustrated in FIG. 1B, the transistor 112 and the transistor 116 may be driven by the output signal that may be present at the output node 108. Accordingly, when the output signal is sufficiently low, the transistor 116 may leave the active mode and effectively turn off because its gate voltage may not be high enough to maintain the transistor 116 in the active mode. The transistor 116 leaving the active mode may cause the transistor 116 and resistor 114 to stop producing the second inductance—consequently the second zero may not be present in the transfer function. However, when the output signal is sufficiently low to effectively turn off the transistor 116, the transistor 112 may be maintained in its active state because it is a PMOS transistor. Therefore, the transistor 112 and the resistor 110 may still produce the first inductance when the output signal is sufficiently low to effectively turn off the transistor 116 such that the first zero may at least partially cancel out the pole even when the second inductance and associated second zero are not present.

Similarly, when the output signal is sufficiently high, the transistor 112 may leave the active mode and effectively turn off because its gate voltage may be too high to maintain the transistor 112 in the active mode. The transistor 112 leaving the active mode may cause the transistor 112 and resistor 110 to stop producing the first inductance—consequently the first zero may not be present in the transfer function. However, when the output signal is sufficiently high to effectively turn off the transistor 112, the transistor 116 may be maintained in its active state because it is an NMOS transistor. Therefore, the transistor 116 and the resistor 114 may still produce the second inductance when the output signal is sufficiently high to effectively turn off the transistor 112 such that the second zero may at least partially cancel out the pole even when the first inductance and associated first zero are not present.

Additionally, in some instances, the output signal may be such that both the transistor 112 and the transistor 116 may be turned on at the same time. In these instances, both the first inductance and the second inductance may be generated and both the first zero and the second zero may at least partially cancel out the pole.

Configuring the bandwidth extension circuit 104 to include the transistor 112 as a PMOS transistor and the transistor 116 as an NMOS transistor as illustrated and described may allow for the output signal to have wider swing in voltages than what would be allowed otherwise while also providing bandwidth extension. However, depending on the voltage ranges in the output signal, in some embodiments the bandwidth extension circuit 104 may omit the resistor 110 and the transistor 112 or may omit the resistor 114 and the transistor 116.

The bandwidth extension circuit 104 may accordingly provide bandwidth extension for the amplifier 100 using active devices, which may reduce the amount of space used to provide bandwidth extension as compared to other circuits or circuit elements that provide bandwidth extension. Modifications, additions, or omissions may be made to the amplifier 100 without departing from the scope of the present disclosure. For example, the amplifier 100 may include more components than those listed. Also, the sizing of the transistor 112 and/or the transistor 116 as well as the resistances of the resistor 110 and/or the resistor 114 may vary according to specific implementations. Further, as indicated above, in some embodiments, the resistor 110 and transistor 112, or the resistor 114 and transistor 116 may be omitted in some embodiments, depending on the voltage ranges of the output signal.

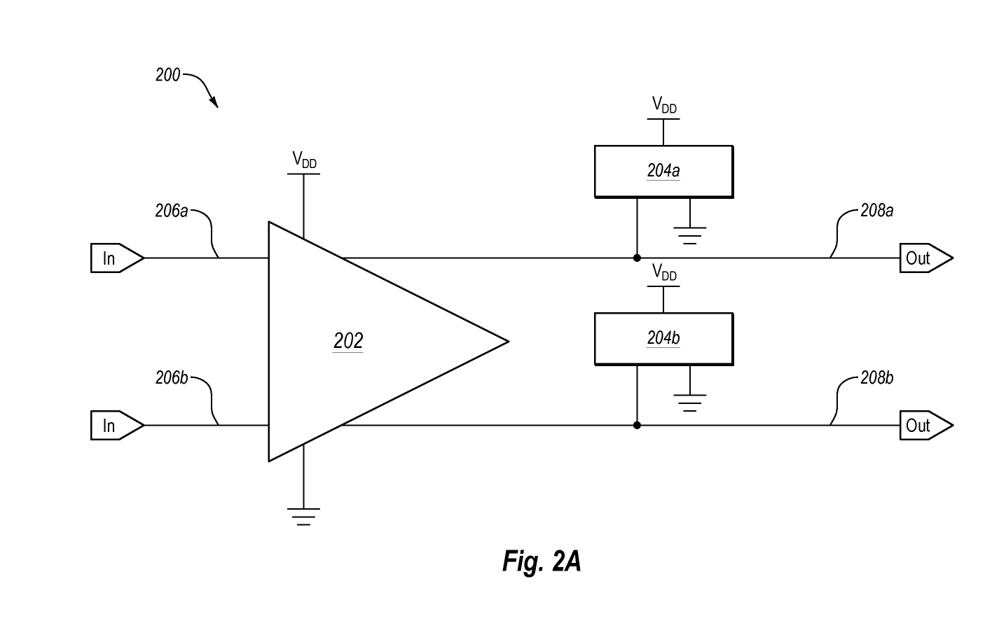

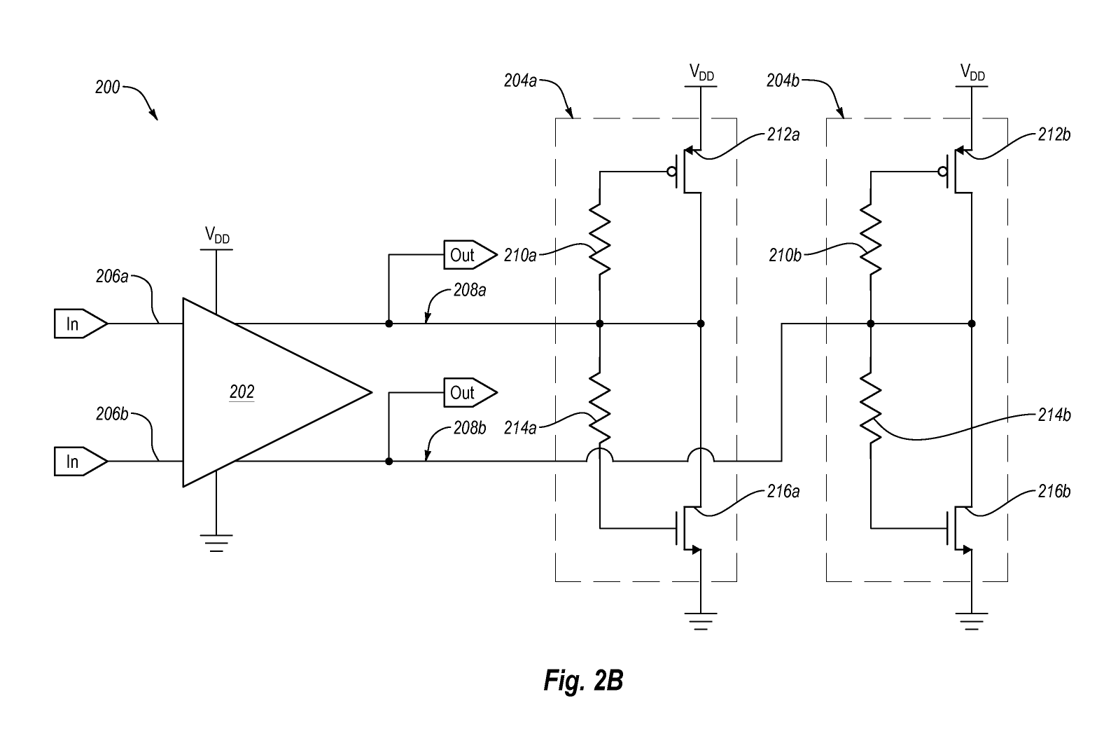

FIG. 2A illustrates an example differential amplifier 200 that includes bandwidth extension circuits 204a and 204b configured to increase a bandwidth of the differential amplifier 200, according to at least one embodiment disclosed herein. The differential amplifier 200 may also include input nodes 206a and 206b, a differential amplifying circuit 202, and output nodes 208a and 208b. The differential amplifying circuit 202 may be any suitable circuit configured to receive differential input signals at the input nodes 206a and 206b, apply a gain to the differential input signals, and output the differential input signals with the applied gain as differential output signals at the output nodes 208a and 208b.

The transfer function of the differential amplifier 200 may have poles that may limit the bandwidth of the differential amplifier 200 and that may correspond to output capacitance at the output nodes 208a and 208b and loading resistances of the differential amplifying circuit 202. Accordingly, similar to the bandwidth extension circuit 104 of FIGS. 1A and 1B, the bandwidth extension circuit 204a and the bandwidth extension circuit 204b may be configured to at least partially cancel out the poles.

For example, the bandwidth extension circuit 204a may be coupled to the output node 208a and the bandwidth extension circuit 204b may be coupled to the output node 208b. The bandwidth extension circuit 204a may be configured to generate an inductance to produce a zero that may at least partially cancel out a pole associated with the output capacitance at the output node 208a and a first loading resistance. Therefore, the bandwidth extension circuit 204a may increase the bandwidth of the differential amplifier 200 with respect to the output signals produced at the output node 208a. The bandwidth extension circuit 204b may be similarly configured to generate an inductance to produce a zero that may at least partially cancel out a pole associated with the output capacitance at the output node 208b and a second loading resistance. Therefore, the bandwidth extension circuit 204b may increase the bandwidth of the differential amplifier 200 with respect to the output signals produced at the output node 208a.

As detailed below with respect to FIG. 2B, in some embodiments, each of the bandwidth extension circuits 204a and 204b may include one or more active device(s) and resistor(s) configured to generate and produce the respective inductances and zeros. In some embodiments, the bandwidth extension circuits 204a and 204b may be configured based on the transfer function of the differential amplifier 200 similar to the bandwidth extension circuit 104 being configured based on the transfer function of the amplifier 100 in FIGS. 1A and 1B.

FIG. 2B illustrates the differential amplifier 200 with an example configuration of the bandwidth extension circuits 204a and 204b, according to at least one embodiment described herein. The bandwidth extension circuits 204a and 204b of FIG. 2B may include resistors 210a and 210b, respectively, resistors 214a and 214b, respectively, as well as PMOS transistors 212a and 212b, respectively, (referred to hereinafter as “transistor 212a” and “transistor 212b”) and NMOS transistors 216a and 216b, respectively (referred to hereinafter as “transistor 216a” and “transistor 216b”). The transistors 212a and 212b, and the transistors 216a and 216b may be the active devices of the bandwidth extension circuits 204a and 204b.

In the illustrated embodiment, the sources of the transistors 212a and 212b may be coupled to a supply voltage V_{DD} and the sources of the transistors 216a and 216b may be coupled to ground. The transistor 212a and the transistor 216a may each be coupled to the output node 208a at their respective drains. Similarly, the transistor 212b and the transistor 216b may each be coupled to the output node 208b at their respective drains. Further, as illustrated in FIG. 2B, the resistor 210a may be coupled between the output node 208a and the gate of the transistor 212a and the resistor 210b may be coupled between the output node 208b and the gate of the transistor 212b. The resistor 214a may be coupled between the output node 208a and the gate of the transistor 216a, and the resistor 214b may be similarly coupled between the output node 208b and the gate of the transistor 216b.

The resistor 210a and the transistor 212a, and the resistor 214a and the transistor 216a may be configured to generate inductances that produce zeros that may at least partially cancel out the pole associated with the output node 208a in a manner analogous to that described for FIG. 1B with respect to the resistor 110, the transistor 112, the resistor 114, and the transistor 116 being configured to produce zeros that may at least partially cancel out the pole associated with the output node 108. In some embodiments, the resistance of the resistor 210a and the resistance of the resistor 214a may be selected to produce the desired zeros as described above with respect to selecting the resistance of the resistors 110 and 114.

Similarly, the resistor 210b and the transistor 212b, and the resistor 214b and the transistor 216b may be configured to generate inductances that produce zeros that may at least partially cancel out the pole associated with the output node 208b in a manner analogous to that described for FIG. 1B with respect to the resistor 110, the transistor 112, the resistor 114, and the transistor 116 being configured to produce zeros that may at least partially cancel out the pole associated with the output node 108. In some embodiments, the resistance of the resistor 210b and the resistance of the resistor 214b may be selected to produce the desired zeros as described above with respect to selecting the resistance of the resistors 110 and 114.

The bandwidth extension circuits 204a and 204b may accordingly provide bandwidth extension for the differential amplifier 200 using active devices, which may reduce the amount of space used to provide bandwidth extension as compared to other bandwidth extension procedures.

Modifications, additions, or omissions may be made to the differential amplifier 200 without departing from the scope of the present disclosure. For example, the differential amplifier 200 may include more components than those listed. Also, the sizing of the transistors 212 and/or the transistors 216 as well as the resistances of the resistors 210 and/or the resistors 214 may vary according to specific implementations. Further, in some embodiments, the resistors 210 and transistors 212, or the resistors 214 and transistors 216 may be omitted in some embodiments, depending on the common mode output range of the differential amplifier 200.

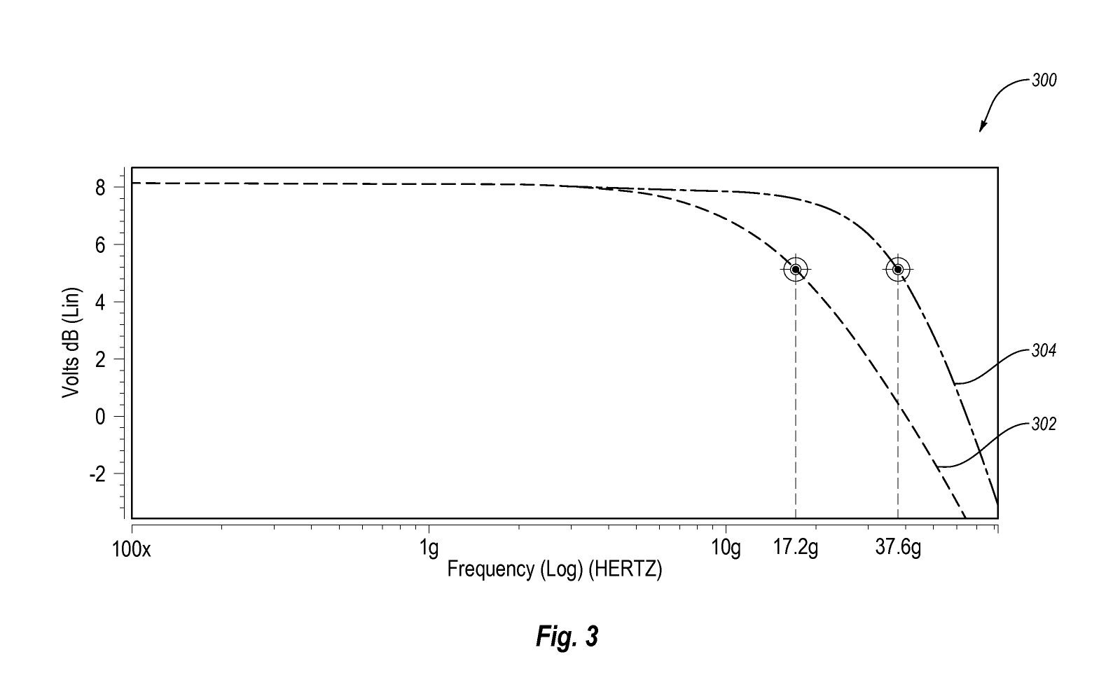

As indicated above, a bandwidth extension circuit described herein may increase the bandwidth of an associated amplifier. FIG. 3 illustrates an example graph 300 that includes example plots 302 and 304 that illustrate that a bandwidth extension circuit described herein may increase the bandwidth of an amplifier, according to at least one embodiment of the present disclosure. The plot 302 represents the frequency response of a differential amplifier that does not include a bandwidth extension circuit described herein and the plot 304 represents the frequency response of the same differential amplifier including a bandwidth extension circuit described herein.

The plot 302 has a three decibel (3 dB) cutoff at approximately 17.2 gigahertz (GHz), which may indicate a bandwidth of about 17.2 GHz for the differential amplifier without a bandwidth extension circuit described herein. By comparison, the plot 304 has a 3 dB cutoff at approximately 37.6 GHz, which may indicate a bandwidth of about 37.6 GHz for the differential amplifier with a bandwidth extension circuit described herein. Accordingly, in the present example, the bandwidth extension circuit may increase the bandwidth of the differential amplifier by a little more than 20 GHz.

FIG. 3 is merely an example of how a bandwidth extension circuit described herein may increase the bandwidth of an amplifier. The frequencies and associated frequency responses listed are merely examples and are not limiting.

All examples and conditional language recited herein are intended for pedagogical objects to aid the reader in understanding the present disclosure and the concepts contributed by the inventor to furthering the art, and are to be construed as being without limitation to such specifically recited examples and conditions. Although embodiments of the present disclosure have been described in detail, it should be understood that the various changes, substitutions, and alterations could be made hereto without departing from the spirit and scope of the present disclosure.

What is claimed is:

1. An amplifier comprising:
an amplifying circuit having an output; and
a bandwidth extension circuit coupled to the output of the amplifying circuit and including an active device and a resistor, the active device and the resistor being configured to create an inductance that increases a bandwidth of the amplifier.

2. The amplifier of claim 1, wherein the active device is a p-type metal-oxide semiconductor (PMOS) transistor.

3. The amplifier of claim 1, wherein the active device is an n-type metal-oxide semiconductor (NMOS) transistor.

4. The amplifier of claim 1, wherein:
the amplifier has a transfer function indicating a frequency response of the amplifier, the transfer function having a pole associated with the bandwidth of the amplifier; and
the active device and the resistor are configured such that the inductance creates a zero for the transfer function that at least partially cancels out the pole such that the bandwidth of the amplifier is increased.

5. The amplifier of claim 4, wherein the zero is approximately equal to the pole.

6. The amplifier of claim 1, wherein the active device is a first active device, the resistor is a first resistor, the inductance is a first inductance, and the bandwidth extension circuit further comprises a second active device and a second resistor configured to create a second inductance that increases the bandwidth of the amplifier, the first active device and the second active device being driven by an output signal of the amplifying circuit, the first active device and the first resistor being configured to create the first inductance when the output signal is sufficiently low to turn off the second active device, the second active device and the second resistor being configured to create the second inductance when the output signal is sufficiently high to turn off the first active device.

7. The amplifier of claim 6, wherein the first active device is a p-type metal-oxide semiconductor (PMOS) transistor and the second active device is an n-type metal-oxide semiconductor (NMOS) transistor.

8. The amplifier of claim 1, wherein the output is a first output, the amplifying circuit is a differential amplifying circuit including the first output and a second output, the bandwidth extension circuit is a first bandwidth extension circuit, the inductance is a first inductance that increases the bandwidth of the amplifier with respect to the first output, and the amplifier further comprises a second bandwidth extension circuit coupled to the second output of the differential amplifying circuit and configured to create a second inductance using another active device where the second inductance increases the bandwidth of the amplifier with respect to the second output.

9. An amplifier comprising:
a node;
an amplifying circuit configured to output an output signal at the node;
a transistor coupled to the node at a drain of the transistor; and
a resistor coupled between the node and a gate of the transistor and configured to have a resistance such that the resistor and the transistor create an inductance that increases a bandwidth of the amplifier.

10. The amplifier of claim 9, wherein the transistor is a p-type metal-oxide semiconductor (PMOS) transistor or an n-type metal-oxide semiconductor (NMOS) transistor.

11. The amplifier of claim 9, wherein:
the amplifier has a transfer function indicating a frequency response of the amplifier, the transfer function having a pole associated with the bandwidth of the amplifier; and
the transistor and the resistor are configured such that the inductance creates a zero for the transfer function that at least partially cancels out the pole such that the bandwidth of the amplifier is increased.

12. The amplifier of claim 11, wherein the zero is approximately equal to the pole.

13. The amplifier of claim 9, wherein the transistor is a first transistor, the resistor is a first resistor, the inductance is a first inductance, and the bandwidth extension circuit further comprises:
a second transistor coupled to the node at a drain of the second transistor; and
a second resistor coupled between the node and a gate of the second transistor and configured to have a resistance such that the second resistor and the second transistor create a second inductance that increases the bandwidth of the amplifier, the first transistor and the second transistor being driven by an output signal of the amplifier, the first transistor and the first resistor being configured to create the first inductance when the output signal is sufficiently low to turn off the second transistor, the second transistor and the second resistor being configured to create the second inductance when the output signal is sufficiently high to turn off the first transistor.

14. The amplifier of claim 13, wherein the first transistor is a PMOS transistor and the second transistor is an NMOS transistor.

15. The amplifier of claim 9, wherein:
the node is a first node and the amplifier further comprises a second node;
the output is a first output;
the amplifying circuit is a differential amplifying circuit including the first output coupled to the first node and a second output coupled to the second node;
the inductance is a first inductance that increases the bandwidth of the amplifier with respect to the first output; and
the amplifier further comprises a second bandwidth extension circuit coupled to the second output of the differential amplifying circuit and configured to create a second inductance using another transistor such that the second inductance increases the bandwidth of the differential amplifier with respect to the second output.

16. A method of increasing bandwidth of an amplifier, the method comprising generating an inductance that increases a bandwidth of the amplifier with a bandwidth extension circuit, which includes an active device and a resistor configured to generate the inductance and coupled to an output node of the amplifier.

17. The method of claim 16, wherein the active device is a PMOS transistor or an NMOS transistor.

18. The method of claim 16, wherein the amplifier has a transfer function that indicates a frequency response of the amplifier, the transfer function having a pole associated with the bandwidth of the amplifier, wherein the method further comprises configuring the active device and the resistor such that the inductance creates a zero for the transfer function that at least partially cancels out the pole such that the bandwidth of the amplifier is increased.

19. The method of claim 18, wherein the zero is approximately equal to the pole.
